(19) United States
(12) Patent Application Publication
(10) Pub. No.: US 2026/0171996 A1
(43) Pub. Date: Jun. 18, 2026

(54) CAVITY-TYPE BULK ACOUSTIC WAVE RESONATOR AND PREPARATION METHOD THEREOF

(71) Applicant: FUJIAN SUNWISE SEMICONDUCTOR TECHNOLOGY CO., LTD., Longyan, Fujian (CN)

(72) Inventors: Mengyuan Wang, Longyan (CN); Jiang Jiang, Longyan (CN); Jiaqi Zhang, Longyan (CN)

(21) Appl. No.: 19/367,851

(22) Filed: Oct. 24, 2025

(30) Foreign Application Priority Data
Dec. 18, 2024 (CN) 202411869920.7
May 13, 2025 (CN) 202510611776.5

(51) Int. Cl. H03H 3/02; H03H 9/17

(52) U.S. Cl. CPC H03H 3/02; H03H 9/173; H03H 2003/021

(57) ABSTRACT

This application provides a cavity-type bulk acoustic wave resonator and a preparation method thereof. The preparation method includes the following steps: (1) forming a piezoelectric layer on a temporary substrate; (2) forming a bottom electrode layer, and patterning the bottom electrode layer; (3) forming a filling layer, and patterning the filling layer,; (4) forming an encapsulation layer to encapsulate the patterned bottom electrode layer and the patterned filling layer; (5) bonding to a transfer substrate; (6) removing the temporary substrate; (7) forming a top electrode layer on the piezoelectric layer, and patterning the top electrode layer; and (8) removing the filling layer to form a cavity. This application can improve various properties of the cavity-type bulk acoustic wave resonator, and reduce the process cost and the process difficulty.

### CROSS REFERENCE TO RELATED APPLICATIONS

The present application claims the benefit of Chinese Patent Application Nos. 2024118699207 filed on December 18, 2024 and 2025106117765 filed on May 13, 2025. All the above are hereby incorporated by reference in their entirety.

### TECHNICAL FIELD

The present disclosure relates to the field of semiconductor radio-frequency (RF) devices, and in particular to a cavity-type bulk acoustic wave resonator and a preparation method thereof.

### BACKGROUND

With rapid development of the 5th-generation mobile communication technology (5G), higher requirements are imposed on performance of RF front-end filters. The large bandwidth and high frequency are two main features of the 5G filters. At present, surface acoustic wave (SAW) filters and bulk acoustic wave (BAW) filters are the most widely used acoustic filters. With the frequencies affected by the sizes of inter digital electrodes (IDEs), the SAW filters are not preferred for frequency bands at 3 GHz or above. Hence, the 5G BAW filters are mainly realized based on a technical route of the polycrystalline aluminum nitride piezoelectric film material. To achieve the large bandwidth (>200 MHz) in the polycrystalline aluminum nitride, scandium doping is employed to cause the high cost and large process difficulty.

In addition, the existing acoustic resonators are generally classified into three types, including backside-etched resonators, solidly-mounted resonators and cavity-type resonators. The backside-etched resonators are difficult for mass production because of the poor mechanical firmness. In spite of the strong mechanical property, the solidly-mounted resonators exhibit the low quality factor (QF) due to the limited effect of the Bragg reflection layer for trapping acoustic waves. Without significant removal of the substrate material, the cavity-type resonators exhibit the strong mechanical stability and high QF. The existing cavity-type resonators are generally prepared in two processes. For the process of forming a recessed cavity in a substrate and then preparing a bottom electrode, a piezoelectric film, and a top electrode, the piezoelectric film is supported poorly to cause cracks. The other process is to form a high-hardness support layer on a substrate, provide a sacrificial layer on a lower portion of the support layer, and remove the sacrificial layer to form a cavity. In this process, although the piezoelectric film is supported firmly, the piezoelectric layer is grown on a surface of the bottom electrode and/or the support layer hardly through an epitaxial manner, resulting in poor crystalline quality to affect various properties of the bulk acoustic wave resonator.

### SUMMARY

A technical problem to be solved by the present disclosure is to provide a cavity-type bulk acoustic wave resonator and a preparation method thereof. The present disclosure can reduce the process cost and the process difficulty, and improves various properties of the cavity-type bulk acoustic wave resonator.

To solve the above technical problems, the present disclosure provides a preparation method of a cavity-type bulk acoustic wave resonator, including the following steps:

(1) forming a piezoelectric layer on a temporary substrate;

(2) forming a bottom electrode layer on the piezoelectric layer, and patterning the bottom electrode layer;

(3) forming a filling layer on the temporary substrate obtained in the step (2), and patterning the filling layer, such that projection of a patterned bottom electrode layer covers a patterned filling layer, where the filling layer is made of silicon dioxide, phosphorus-doped silica or resin;

(4) forming an encapsulation layer on the temporary substrate obtained in the step (3) to encapsulate the patterned bottom electrode layer and the patterned filling layer, and cover other regions of the temporary substrate, where the encapsulation layer is made of silicon or ceramic;

(5) bonding the temporary substrate obtained in the step (4) to a transfer substrate;

(6) removing the temporary substrate to expose the piezoelectric layer;

(7) forming a top electrode layer on the piezoelectric layer, and patterning the top electrode layer, such that projection of the patterned filling layer covers a patterned top electrode layer; and

(8) removing the filling layer to form a cavity, thereby obtaining the cavity-type bulk acoustic wave resonator.

As an improvement to the above technical solution, a distance between an outer edge of the patterned filling layer and an outer edge of the projection of the patterned bottom electrode layer is ≤3 μm; and/or a distance between an outer edge of the patterned top electrode layer and an outer edge of the projection of the patterned filling layer is ≤3 μm.

As an improvement to the above technical solution, the patterned filling layer, the patterned top electrode layer, and the patterned bottom electrode layer are all pentagonal;

a distance between an outer edge of the patterned filling layer and an outer edge of the projection of the patterned bottom electrode layer is 2.2-2.8 μm; and a distance between an outer edge of the patterned top electrode layer and an outer edge of the projection of the patterned filling layer is 2.2-2.8 μm.

As an improvement to the above technical solution, the temporary substrate is selected from one or more of a sapphire substrate, a silicon carbide substrate, a silicon nitride substrate or a silicon substrate; and/or the transfer substrate is selected from one or more of a silicon substrate, a sapphire substrate, a silicon carbide substrate or a diamond substrate.

As an improvement to the above technical solution, the piezoelectric layer is made of monocrystalline aluminum nitride and/or monocrystalline epsilon-gallium oxide, with a thickness of 200-1,000 nm; and/or the bottom electrode layer is made of one or more of tungsten, molybdenum and aluminum, with a thickness of 100-500 nm; and/or the filling layer has a thickness of 100-2,000 nm; and/or the top electrode layer is made of one or more of tungsten, molybdenum and aluminum, with a thickness of 50-500 nm.

As an improvement to the above technical solution, the encapsulation layer has a thickness of D; and the filling layer and the bottom electrode layer have a total thickness of d, D-d≥300 nm.

As an improvement to the above technical solution, the step (5) includes: grinding and planarizing the encapsulation layer, and then bonding the encapsulation layer to the transfer substrate; and a ground and planarized encapsulation layer has a surface roughness of ≤0.3 nm, a uniformity of ≤1%, and a total thickness variation (TTV) of ≤20 μm.

As an improvement to the above technical solution, the step (6) includes: grinding the temporary substrate to 5-50 μm, and removing a remaining temporary substrate by dry etching to expose the piezoelectric layer.

As an improvement to the above technical solution, the piezoelectric layer is made of the monocrystalline epsilon-gallium oxide.

Accordingly, the present disclosure further provides a cavity-type bulk acoustic wave resonator, which is prepared with the preparation method of a cavity-type bulk acoustic wave resonator.

The present disclosure has the following beneficial effects:

According to the preparation method of a cavity-type bulk acoustic wave resonator in the embodiment of the present disclosure, the piezoelectric layer is epitaxially grown on the temporary substrate first. Then, the bottom electrode layer, the filling layer and the encapsulation layer are prepared. The transfer substrate is bonded. The temporary substrate is removed to expose the piezoelectric layer. The top electrode layer is formed. The preparation method not only effectively improves the crystalline quality of the piezoelectric layer through epitaxial growth, but also forms the top electrode layer and the bottom electrode layer by bonding, reducing the production difficulty, and providing solutions for the preparation of the cavity-type bulk acoustic wave resonator.

### BRIEF DESCRIPTION OF THE DRAWINGS

FIG. 1 is a schematic structural sectional view of a temporary substrate after Step S2 according to an embodiment of the present disclosure;

FIG. 2 is a schematic structural sectional view of a temporary substrate after Step S3 according to an embodiment of the present disclosure;

FIG. 3 is a schematic structural sectional view of a temporary substrate after Step S4 according to an embodiment of the present disclosure;

FIG. 4 is a schematic structural sectional view of a temporary substrate after Step S5 according to an embodiment of the present disclosure;

FIG. 5 is a schematic structural sectional view of a transfer substrate after Step S7 according to an embodiment of the present disclosure;

FIG. 6 is a schematic structural top view of a transfer substrate after Step S7 according to an embodiment of the present disclosure;

FIG. 7 is a schematic structural view of a through hole in Step S8 according to an embodiment of the present disclosure; and

FIG. 8 is a schematic structural sectional view of a cavity-type bulk acoustic wave resonator according to an embodiment of the present disclosure.

In the figures: 1: temporary substrate, 2: piezoelectric layer, 3: bottom electrode layer, 4: filling layer, 5: encapsulation layer, 6: transfer substrate, 7: upper electrode, 8: cavity, and 9: through hole.

### DETAILED DESCRIPTION

To make the objectives, technical solutions, and advantages of the present disclosure clearer, the present disclosure is further described in detail below with reference to the drawings and embodiments. The examples of the embodiments are shown in the accompanying drawings. The same or similar numerals represent the same or similar elements or elements with the same or similar functions throughout the specification. The embodiments described below with reference to the drawings are exemplary, and are merely intended to explain the present disclosure, rather than to limit the present disclosure. It should be understood that the specific embodiments described herein are merely intended to explain the present disclosure, rather than to limit the present disclosure.

In the description of the present disclosure, it needs to be understood the orientation or positional relationships indicated by terms, such as ''length'', ''width'', ''upper'', ''lower'', ''left'', ''right'', ''horizontal'', ''top'', and ''bottom'', are based on the orientation or positional relationship shown in the accompanying drawings, are merely for facilitating the description of the present disclosure and simplifying the description, rather than indicating or implying that an apparatus or element referred to must have a particular orientation or be constructed and operated in a particular orientation, and therefore shall not be interpreted as limiting the present disclosure.

In the description of the present disclosure, it should be noted that unless otherwise expressly specified, terms such as "mounted", "connected to", and "connected with" should be comprehended in a broad sense. For example, the "connection" may be a fixed connection, a removable connection, or an integral connection; may be a mechanical connection, an electrical connection, or mutual communication; may be a direct connection or an indirect connection via an intermediate medium; or may be an interconnection or an interaction relationship between two elements. Those of ordinary skill in the art may understand specific meanings of the above terms in the present disclosure based on specific situations.

In the present disclosure, unless otherwise expressly specified and defined, that a first feature is "above" or "under" a second feature may include that the first feature is in direct contact with the second feature, or that the first feature and the second feature are not in direct contact with each other but are in contact by using another feature between them. In addition, that the first feature is "over", "above", and "on" the second feature includes that the first feature is directly above and diagonally above the second feature, or simply indicates that a horizontal height of the first feature is larger than that of the second feature. That the first feature is "under" and "below" the second feature includes that the first feature is directly under or obliquely under the second feature, or simply indicates that the horizontal height of the first feature is lower than that of the second feature.

The disclosure below provides a number of different embodiments or examples used to implement different structures of the present disclosure. To simplify the disclosure of the present disclosure, components and dispositions of particular examples are described below. Certainly, the descriptions are only examples and are not intended to limit the present disclosure. In addition, reference numerals and/or reference letters may be repeated in different examples in the present disclosure, and such repetition is for purposes of simplification and clarity and is not indicative of relationships between the embodiments and/or dispositions discussed. In addition, while the present disclosure provides examples of various specific processes and materials, the person of ordinary skill in the art may be aware of applications of other processes and/or use of other materials.

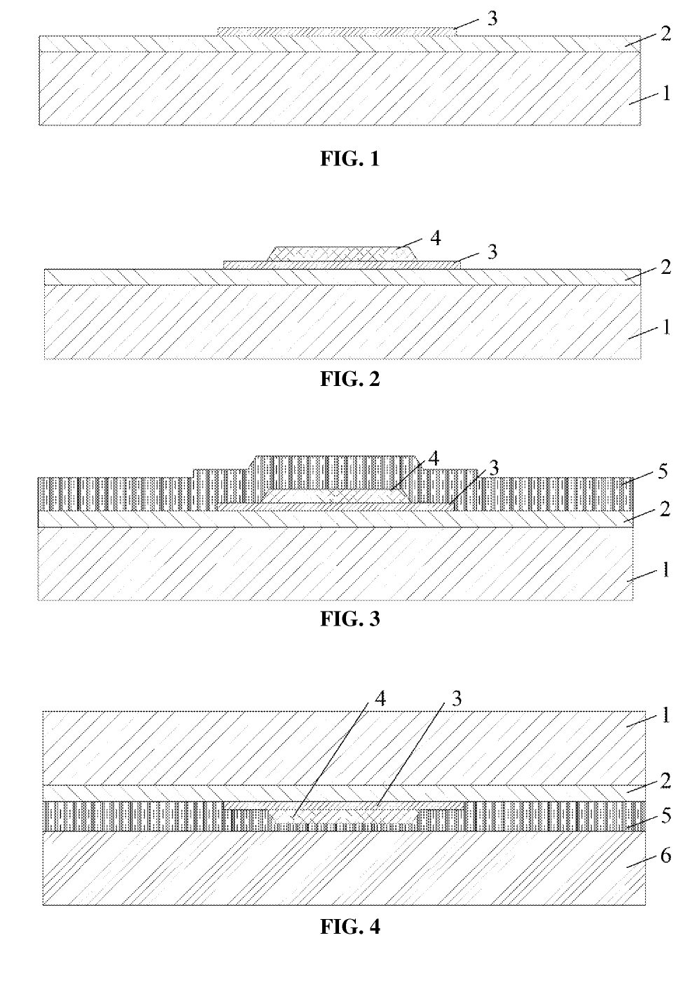

Referring to FIG. 1 to FIG. 7, an embodiment of the present disclosure provides a preparation method of a cavity-type bulk acoustic wave resonator, including the following steps:

S1: A piezoelectric layer is formed on a temporary substrate.

The temporary substrate 1 may be a sapphire substrate, a silicon substrate, a quartz substrate, a silicon carbide substrate, a silicon nitride substrate, and a gallium arsenide substrate, but is not limited thereto. Preferably, the temporary substrate 1 is the sapphire substrate, the silicon carbide substrate, the silicon nitride substrate or the silicon substrate, more preferably the silicon substrate.

The piezoelectric layer 2 is made of one or more of polycrystalline aluminum nitride, monocrystalline aluminum nitride or monocrystalline epsilon-gallium oxide, but is not limited thereto. Preferably, the piezoelectric layer 2 is made of the monocrystalline aluminum nitride and/or the monocrystalline epsilon-gallium oxide. More preferably, the piezoelectric layer 2 is made of the monocrystalline epsilon-gallium oxide, and prepared epitaxially. The monocrystalline epsilon-gallium oxide has a piezoelectric coefficient twice a piezoelectric coefficient of the monocrystalline aluminum nitride, being more advantageous in large bandwidth and low loss.

The piezoelectric layer 2 has a thickness of 100-1,000 nm. Exemplarily, the thickness is 150 nm, 300 nm, 450 nm, 600 nm, 750 nm or 900 nm, but is not limited thereto. Preferably, the thickness is 200-1,000 nm.

Specifically, a polycrystalline material layer may be grown by physical vapor deposition (PVD), or a monocrystalline material layer may be grown by metal organic chemical vapor deposition (MOCVD), molecular beam epitaxy (MBE) or pulsed laser deposition (PLD), to serve as the piezoelectric layer 2, but is not limited thereto. Preferably, in the embodiment, a monocrystalline epsilon-gallium oxide layer is grown by the MOCVD, with high preparation efficiency and desirable piezoelectric property.

S2: A bottom electrode layer is formed on the piezoelectric layer, and patterned.

The bottom electrode layer 3 is made of one or more of tungsten, molybdenum and aluminum, but is not limited thereto. The bottom electrode layer 3 has a thickness of 100-800 nm. Exemplarily, the thickness is 150 nm, 200 nm, 300 nm, 450 nm, 600 nm or 700 nm, but is not limited thereto. Preferably, the bottom electrode layer 3 has the thickness of 100-500 nm, more preferably 100-300 nm.

The bottom electrode layer 3 may be grown by PVD, evaporation and the like, but is not limited thereto. Preferably, in the embodiment, the bottom electrode layer 3 is grown by the PVD. The grown bottom electrode layer 3 is patterned by photoetching. The photoetching may be dry etching or wet etching. Preferably, the bottom electrode layer 3 is etched by the dry etching.

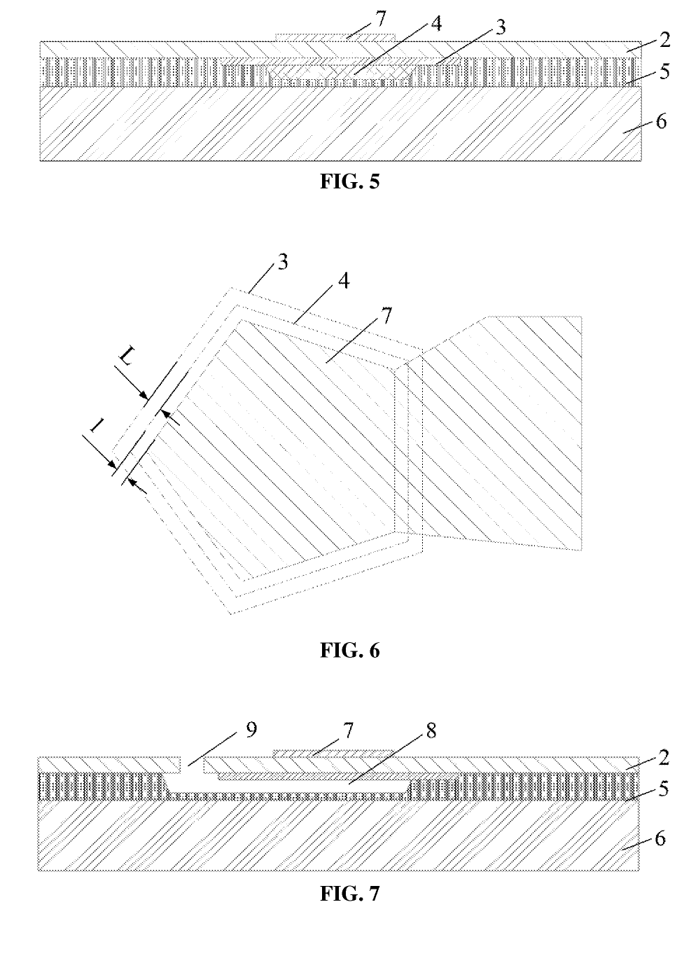

Specifically, a cross section of the patterned bottom electrode layer 3 is a circle, a triangle, a rectangle or pentagon, but is not limited thereto. Preferably, referring to FIG. 1 and FIG. 6, the cross section of the patterned bottom electrode layer 3 is a regular pentagon.

S3: A filling layer is formed on the temporary substrate obtained in Step S2, and patterned, such that projection of a patterned bottom electrode layer covers a patterned filling layer.

The filling layer 4 is made of silicon dioxide, phosphorus-doped silica or resin, but is not limited thereto. The filling layer 4 made of these materials can be removed conveniently in a later period. Preferably, the filling layer 4 is made of the phosphorus-doped silica, namely phosphorosilicate glass.

The filling layer 4 has a thickness of 100-2,000 nm, so as to form a larger cavity 8, improving various properties of the cavity-type bulk acoustic wave resonator. Exemplarily, the filling layer 4 has the thickness of 400 nm, 800 nm, 1,200 nm, 1,500 nm or 1,800 nm, but is not limited thereto. Preferably, the filling layer 4 has the thickness of 500-1,000 nm.

Specifically, the filling layer 4 may be formed by MOCVD, plasma-enhanced chemical vapor deposition (PECVD), spin coating, and the like, but is not limited thereto. The formed filling layer 4 is patterned by photoetching. The photoetching may be dry etching or wet etching. Preferably, the filling layer 4 is etched by the dry etching.

Specifically, the filling layer 4 is formed on the bottom electrode layer 3. A size of the patterned filling layer 4 is less than a size of the patterned bottom electrode layer 3. That is, projection of the patterned bottom electrode layer 3 on a plane of the filling layer 4 completely covers the patterned filling layer 4. Specifically, a cross section of the patterned filling layer 4 is a circle, a triangle, a rectangle or pentagon, but is not limited thereto. Preferably, referring to FIG. 2 and FIG. 6, the cross section of the patterned filling layer 4 is a regular pentagon.

Specifically, both the size of the patterned filling layer 4 and the size of the patterned bottom electrode layer 3 are a size of a cross section. Specifically, when the cross section is a circle, the size is a diameter. When the cross section is a rectangle, the size is a length of a long side. When the cross section is a triangle, the size is a length of a longest side. When the cross section is a pentagon, the size is a maximum of a height of the pentagon. When the cross section is other polygons, the size is a maximum of a height of each of the polygons, but is not limited thereto.

Specifically, a cross-sectional shape of the patterned filling layer 4 and a cross-sectional shape of the patterned bottom electrode layer 3 are the same or different. Preferably, in an embodiment, the cross section of the patterned filling layer 4 and the cross section of the patterned bottom electrode layer 3 are a regular pentagon. The two cross sections are parallel to each other in five edges.

Referring to FIG. 6, a distance L between an outer edge of the patterned filling layer 4 and an outer edge of the projection of the patterned bottom electrode layer 3 is ≤3 μm. Exemplarily, the distance L is 0.8 μm, 1.2 μm, 2 μm or 2.4 μm, but is not limited thereto. Preferably, the distance L is 2.2-2.8 μm.

S4: An encapsulation layer is formed on the temporary substrate obtained in Step S3 to encapsulate the patterned bottom electrode layer and the patterned filling layer, and cover other regions of the temporary substrate.

The encapsulation layer 5 is made of a high hardness material, so as to desirably support the piezoelectric layer 2, a top electrode layer 7 and the bottom electrode layer 3 after the cavity 8 is formed in the later period. Specifically, the encapsulation layer 5 may be made of silicon or ceramic, but is not limited thereto.

Specifically, referring to FIG. 3, in order to form the desirable support, a thickness D of the encapsulation layer 5 should be greater than a total thickness d of the filling layer 4 and the bottom electrode layer 3. That is, the encapsulation layer 5 completely encapsulates the bottom electrode layer 3, the filling layer 4 and an exposed surface of the temporary substrate 1. Preferably, D-d ≥ 300 nm. More specifically, the encapsulation layer 5 has a thickness of 1,000-3,000 nm. Exemplarily, the thickness is 1,200 nm, 1,400 nm, 1,800 nm, 2,200 nm, 2,600 nm or 2,800 nm, but is not limited thereto.

The encapsulation layer 5 may be prepared by chemical vapor deposition (CVD) (such as MOCVD or PECVD) or PVD, but is not limited thereto.

S5: The temporary substrate obtained in Step S4 is bonded to a transfer substrate.

The transfer substrate 6 may be a sapphire substrate, a silicon substrate, a quartz substrate, a silicon carbide substrate, a silicon nitride substrate, and a gallium arsenide substrate, but is not limited thereto. Preferably, the temporary substrate 1 is one or more of the silicon substrate, the sapphire substrate, the silicon carbide substrate or the diamond substrate, more preferably the silicon substrate. Preferably, for ease of bonding, the transfer substrate 6 may further be provided with a silicon layer, a silicon dioxide layer or other non-metal insulating layers, but is not limited thereto. These materials facilitate direct bonding of the encapsulation layer 5.

The temporary substrate 1 obtained in Step S4 and the transfer substrate 6 may be bonded by eutectic bonding, anodic bonding, thermocompression bonding or direct bonding, but are not limited thereto. Preferably, the direct bonding is used.

Preferably, in some implementations, before bonded, the encapsulation layer 5 is ground and polished by chemical mechanical polishing (CMP), such that the encapsulation layer 5 is planarized to facilitate subsequent bonding. Specifically, after ground and polished, the encapsulation layer 5 has a surface roughness of ≤0.3 nm, a uniformity of ≤1%, and a TTV of ≤20 μm. The surface roughness, the uniformity and the TTV may be measured with reference to GB/T 32814-2016.

S6: The temporary substrate is removed to expose the piezoelectric layer.

The temporary substrate 1 may be removed by chemical grinding, etching or laser lift-off. Preferably, in an embodiment, the temporary substrate 1 is ground to 5-50 μm, and a remaining temporary substrate 1 is removed by dry etching to expose the piezoelectric layer 2.

S7: A top electrode layer is formed on the piezoelectric layer, and patterned.

The top electrode layer 7 is made of one or more of tungsten, molybdenum and aluminum, but is not limited thereto. The top electrode layer 7 has a thickness of 50-800 nm. Exemplarily, the thickness is 80 nm, 150 nm, 200 nm, 300 nm, 450 nm, 600 nm or 700 nm, but is not limited thereto. Preferably, the top electrode layer 7 has the thickness of 50-500 nm, more preferably 100-300 nm.

The top electrode layer 7 may be grown by PVD, evaporation and the like, but is not limited thereto. Preferably, in the embodiment, the top electrode layer 7 is grown by the PVD. The grown top electrode layer 7 is patterned by photoetching. The photoetching may be dry etching or wet etching. Preferably, the top electrode layer 7 is etched by the dry etching.

Specifically, the top electrode layer 7 is formed on the patterned filling layer 4. A size of the patterned top electrode layer 7 is less than the size of the patterned filling layer 4. That is, projection of the patterned filling layer 4 on a plane of the top electrode layer 7 completely covers the patterned top electrode layer 7. Specifically, a cross section of the patterned top electrode layer 7 is a circle, a triangle, a rectangle or pentagon, but is not limited thereto. Preferably, referring to FIG. 5 and FIG. 6, the cross section of the patterned top electrode layer 7 is a regular pentagon.

Specifically, both the size of the patterned filling layer 4 and the size of the patterned top electrode layer 7 are a size of a cross section. Specifically, when the cross section is a circle, the size is a diameter. When the cross section is a rectangle, the size is a length of a long side. When the cross section is a triangle, the size is a length of a longest side. When the cross section is a pentagon, the size is a maximum of a height of the pentagon. When the cross section is other polygons, the size is a maximum of a height of each of the polygons, but is not limited thereto.

Specifically, a cross-sectional shape of the patterned filling layer 4 and a cross-sectional shape of the patterned top electrode layer 7 are the same or different. Preferably, in an embodiment, the cross section of the patterned filling layer 4 and the cross section of the patterned top electrode layer 7 are a regular pentagon. The two cross sections are parallel to each other in five edges.

Referring to FIG. 6, a distance l between an outer edge of the patterned top electrode layer 7 and an outer edge of the projection of the patterned filling layer 4 is ≤3 μm. Exemplarily, the distance l is 0.8 μm, 1.2 μm, 2 μm or 2.4 μm, but is not limited thereto. Preferably, the distance l is 2.2-2.8 μm.

S8: The filling layer is removed to form a cavity, thereby obtaining the cavity-type bulk acoustic wave resonator.

A through hole 9 (refer to FIG. 7) may be formed by etching the piezoelectric layer 2. The filling layer 4 is then removed by etching to form the cavity 8, thereby obtaining the cavity-type bulk acoustic wave resonator.

According to the preparation method of a cavity-type bulk acoustic wave resonator in the present disclosure, the piezoelectric layer 2 is epitaxially grown on the temporary substrate 1 first. Then, the bottom electrode layer 3, the filling layer 4 and the encapsulation layer 5 are prepared. The transfer substrate 6 is bonded. The temporary substrate 1 is removed to expose the piezoelectric layer 2. The top electrode layer 7 is formed. The preparation method not only effectively improves the crystalline quality of the piezoelectric layer 2 through epitaxial growth, but also forms the top electrode layer 7 and the bottom electrode layer 3 by bonding, reducing the production difficulty, and providing solutions for the preparation of the cavity-type bulk acoustic wave resonator. It is to be noted that the epitaxially grown piezoelectric layer 2 can improve the crystalline quality, but there are no other layers (such as the bottom electrode layer 3) between the substrate and the piezoelectric layer 2. In this way, the bottom electrode layer 3 cannot be prepared under the piezoelectric layer 2 in advance, and thus the process is highly difficult and realized hardly. The present disclosure solves this problem through the special preparation process.

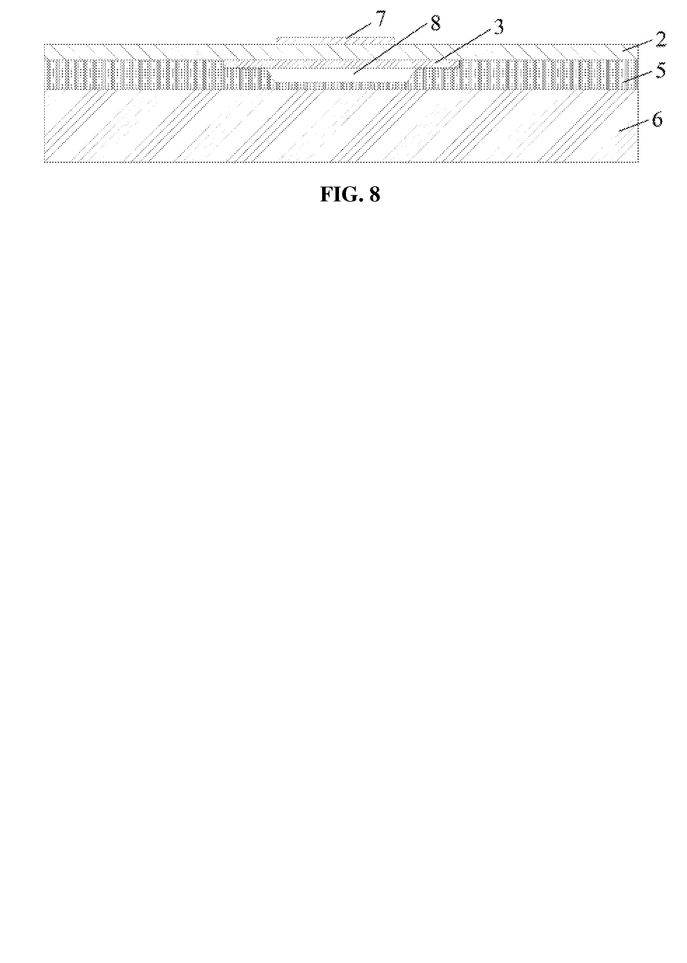

Accordingly, an embodiment of the present disclosure further provides a cavity-type bulk acoustic wave resonator, as shown in FIG. 8, which is prepared with the above preparation method. Preferably, the cavity-type bulk acoustic wave resonator in the embodiment may further include a common Bragg reflection layer in the field, and the like, but is not limited thereto.

The above are merely preferred implementations of the present disclosure. It should be noted that a person of ordinary skill in the art may further make several improvements and modifications without departing from the principle of the present disclosure, but such improvements and modifications should be deemed as falling within the protection scope of the present disclosure.

1. A preparation method of a cavity-type bulk acoustic wave resonator, comprising the following steps:
(1) forming a piezoelectric layer on a temporary substrate;
(2) forming a bottom electrode layer on the piezoelectric layer, and patterning the bottom electrode layer;
(3) forming a filling layer on the temporary substrate obtained in the step (2), and patterning the filling layer, such that projection of a patterned bottom electrode layer covers a patterned filling layer, wherein the filling layer is made of silicon dioxide, phosphorus-doped silica or resin;
(4) forming an encapsulation layer on the temporary substrate obtained in the step (3) to encapsulate the patterned bottom electrode layer and the patterned filling layer, and cover other regions of the temporary substrate, wherein the encapsulation layer is made of silicon or ceramic;
(5) bonding the temporary substrate obtained in the step (4) to a transfer substrate;
(6) removing the temporary substrate to expose the piezoelectric layer;
(7) forming a top electrode layer on the piezoelectric layer, and patterning the top electrode layer, such that projection of the patterned filling layer covers a patterned top electrode layer; and
(8) removing the filling layer to form a cavity, thereby obtaining the cavity-type bulk acoustic wave resonator.

2. The preparation method of a cavity-type bulk acoustic wave resonator according to claim 1, wherein a distance between an outer edge of the patterned filling layer and an outer edge of the projection of the patterned bottom electrode layer is less than or equal to 3 μm; and/or
a distance between an outer edge of the patterned top electrode layer and an outer edge of the projection of the patterned filling layer is less than or equal to 3 μm.

3. The preparation method of a cavity-type bulk acoustic wave resonator according to claim 1, wherein the patterned filling layer, the patterned top electrode layer, and the patterned bottom electrode layer are all pentagonal;
a distance between an outer edge of the patterned filling layer and an outer edge of the projection of the patterned bottom electrode layer is 2.2-2.8 μm; and
a distance between an outer edge of the patterned top electrode layer and an outer edge of the projection of the patterned filling layer is 2.2-2.8 μm.

4. The preparation method of a cavity-type bulk acoustic wave resonator according to claim 1, wherein the temporary substrate is selected from one or more of a sapphire substrate, a silicon carbide substrate, a silicon nitride substrate or a silicon substrate; and/or
the transfer substrate is selected from one or more of a silicon substrate, a sapphire substrate, a silicon carbide substrate or a diamond substrate.

5. The preparation method of a cavity-type bulk acoustic wave resonator according to claim 1, wherein the piezoelectric layer is made of monocrystalline aluminum nitride and/or monocrystalline epsilon-gallium oxide, with a thickness of 200-1,000 nm; and/or
the bottom electrode layer is made of one or more of tungsten, molybdenum and aluminum, with a thickness of 100-500 nm; and/or
the filling layer has a thickness of 100-2,000 nm; and/or
the top electrode layer is made of one or more of tungsten, molybdenum and aluminum, with a thickness of 50-500 nm.

6. The preparation method of a cavity-type bulk acoustic wave resonator according to claim 1, wherein the encapsulation layer has a thickness of D; and the filling layer and the bottom electrode layer have a total thickness of d, D-d is greater than or equal to 300 nm.

7. The preparation method of a cavity-type bulk acoustic wave resonator according to claim 1, wherein the step (5) comprises: grinding and planarizing the encapsulation layer, and then bonding the encapsulation layer to the transfer substrate; and
a ground and planarized encapsulation layer has a surface roughness of less than or equal to 0.3 nm, a uniformity of less than or equal to 1%, and a total thickness variation (TTV) of less than or equal to 20 μm.

8. The preparation method of a cavity-type bulk acoustic wave resonator according to claim 1, wherein the step (6) comprises: grinding the temporary substrate to 5-50 μm, and removing a remaining temporary substrate by dry etching to expose the piezoelectric layer.

9. The preparation method of a cavity-type bulk acoustic wave resonator according to claim 1, wherein the piezoelectric layer is made of the monocrystalline epsilon-gallium oxide.

10. A cavity-type bulk acoustic wave resonator, prepared with the preparation method of a cavity-type bulk acoustic wave resonator according to claim 1.

11. A cavity-type bulk acoustic wave resonator, prepared with the preparation method of a cavity-type bulk acoustic wave resonator according to claim 2.

12. A cavity-type bulk acoustic wave resonator, prepared with the preparation method of a cavity-type bulk acoustic wave resonator according to claim 3.

13. A cavity-type bulk acoustic wave resonator, prepared with the preparation method of a cavity-type bulk acoustic wave resonator according to claim 4.

14. A cavity-type bulk acoustic wave resonator, prepared with the preparation method of a cavity-type bulk acoustic wave resonator according to claim 5.

15. A cavity-type bulk acoustic wave resonator, prepared with the preparation method of a cavity-type bulk acoustic wave resonator according to claim 6.

16. A cavity-type bulk acoustic wave resonator, prepared with the preparation method of a cavity-type bulk acoustic wave resonator according to claim 7.

17. A cavity-type bulk acoustic wave resonator, prepared with the preparation method of a cavity-type bulk acoustic wave resonator according to claim 8.

18. A cavity-type bulk acoustic wave resonator, prepared with the preparation method of a cavity-type bulk acoustic wave resonator according to claim 9.
